(19) United States
(12) Patent Application Publication
(10) Pub. No.: US 2013/0088841 A1
(43) Pub. Date: Apr. 11, 2013

(54) SUBSTRATE WITH BUILT-IN FUNCTIONAL ELEMENT

(71) Applicants: Daisuke Ohshima, Tokyo (JP); Kentaro Mori, Tokyo (JP); Yoshiki Nakashima, Tokyo (JP); Katsumi Kikuchi, Tokyo (JP); Shintaro Yamamichi, Tokyo (JP)

(72) Inventors: Daisuke Ohshima, Tokyo (JP); Kentaro Mori, Tokyo (JP); Yoshiki Nakashima, Tokyo (JP); Katsumi Kikuchi, Tokyo (JP); Shintaro Yamamichi, Tokyo (JP)

(73) Assignee: NEC Corporation, Tokyo (JP)

(21) Appl. No.: 13/639,486

(22) PCT Filed: Jan. 19, 2011
(86) PCT No.: PCT/JP2011/050874

§ 371 Date: Dec. 17, 2012

(30) Foreign Application Priority Data
Apr. 6, 2010 (JP) 2010-087804

(51) Int. Cl. H05K 1/18

(52) U.S. Cl. CPC H05K 1/183
USPC 361/761

(57) ABSTRACT

The present invention has an object to provide a substrate with a built-in functional element, including the functional element above a metal plate, in which crosstalk noise between signal wirings can be reduced and higher characteristic impedance matching can be achieved. An aspect of the present invention provides a substrate with a built-in functional element, including: a metal plate that includes a concave portion and serves as a ground; the functional element that is placed in the concave portion and includes an electrode terminal; a first insulating layer that covers the functional element and is placed in contact with the metal plate; a first wiring layer including first signal wiring that is opposite the metal plate with the first insulating layer being interposed therebetween; a second insulating layer that covers the first wiring layer; and a ground layer formed of a ground plane that is opposite the first wiring layer with the second insulating layer being interposed therebetween.

### TECHNICAL FIELD

The present invention relates to a substrate with a built-in functional element, including one or more built-in functional elements such as semiconductor chips and an electronic device including the substrate with a built-in functional element.

### BACKGROUND ART

Along with increasing demand for a higher information processing capacity, the operation of a semiconductor element is sped up, and the number of switchings is increased, so that signal wiring is required to have improved electrical characteristics, for example, matched characteristic impedance and reduction in crosstalk noise with another signal wiring. Consequently, in order to deal with such a demand, according to Patent Literature 1, the wiring structure of signal wiring is formed into a stripline structure, and large-area ground layers are respectively formed above and below the signal wiring with the intermediation of insulating layers.

In addition, in a conventional wiring circuit substrate, signal wirings in the same layer are close to each other, and crosstalk noise thus occurs between the signal wirings, which results in an operation failure of the driving element of the circuit. This appears more remarkably in a circuit that has a higher operation frequency (for example, 100 MHz or higher). In order to prevent such crosstalk noise between signal wirings in the same layer, conventionally, a ground layer is placed between the signal wirings.

Meanwhile, for the purpose of achieving higher integration and higher function of an electronic device such as a semiconductor device, there is proposed a package technique for a built-in functional element such as a semiconductor element, in other words, a so-called built-in functional element technique. In a substrate with a built-in functional element, the functional element is built in the substrate, whereby the bonding area of the functional element can be reduced. This technique is expected as a high-density mounting technique that achieves higher integration and higher function of the semiconductor device and achieves a reduced thickness, lower costs, high frequency support, low-stress connection, and the like of the package.

For example, Patent Literature 2 discloses a substrate with a built-in semiconductor element, in which: a semiconductor chip 1002 is placed above a metal plate 1001 serving as a support, with the intermediation of an adhesive agent 1003 with a circuit surface of the semiconductor chip 1002 facing upward; the semiconductor chip is buried in an insulating layer 1004; and a wiring layer 1005 is laminated on the insulating layer (see FIG. 20). According to Patent Literature 2, because the metal plate 1001 is used as the support of the semiconductor chip 1002, warpage of the semiconductor chip can be reduced, and the provided substrate with a built-in semiconductor element can have an excellent heat radiating property.

### CITATION LIST

### Patent Literature

Patent Literature 1: JP2008-263239A
Patent Literature 2: JP3277997B

### SUMMARY OF INVENTION

### Technical Problem

As described above, the substrate with a built-in functional element is advantageous in higher integration density and increased function, and the technique as disclosed in Patent Literature 2, in which a functional element such as a semiconductor chip is placed to be built in a support plate made of metal, is excellent as regards reducing warpage in the functional element and in the substrate itself and as regards a property for radiating heat.

In addition, along with higher function of an electronic device, the clock frequency is increasingly higher, and characteristic impedance matching of a substrate circuit is becoming more and more important.

In view of the above, the present invention has an object to provide a substrate with a built-in functional element, including the functional element above a metal plate, in which crosstalk noise between signal wirings can be reduced and higher characteristic impedance matching can be achieved.

### Solution to Problem

In view of the above, a first aspect of the present invention provides a substrate with a built-in functional element, including:

a metal plate that includes a concave portion and serves as a ground;

the functional element that is placed in the concave portion and includes an electrode terminal;

a first insulating layer that covers the functional element and is placed in contact with the metal plate;

a first wiring layer including first signal wiring that is opposite the metal plate with the first insulating layer being interposed therebetween;

a second insulating layer that covers the first wiring layer; and

a ground layer formed of a ground plane that is opposite the first wiring layer with the second insulating layer being interposed therebetween.

In addition, a second aspect of the present invention provides a substrate with a built-in functional element, including:

the functional element including an electrode terminal;

a metal plate that supports the functional element and serves as a ground;

a first insulating layer that covers the functional element and is placed in contact with the metal plate;

a first wiring layer including first signal wiring that is opposite the metal plate with the first insulating layer being interposed therebetween;

a second insulating layer that covers the first wiring layer; and

a ground layer formed of a ground plane that is opposite the first wiring layer with the second insulating layer being interposed therebetween, wherein

assuming that: a shortest distance between the metal plate and the first signal wiring is d1; a distance between the first signal wiring and the ground layer is d2; a permittivity of the first insulating layer is ε1; and a permittivity of the second insulating layer is ε2, ε1/d1 is equal to or more than ε2/d2.

### Advantageous Effects of Invention

According to the present invention, it is possible provide a substrate with a built-in functional element, including the functional element above a metal plate, in which crosstalk noise between signal wirings can be reduced and characteristic impedance matching can be achieved.

### BRIEF DESCRIPTION OF DRAWINGS

FIG. 1 is an outline cross-sectional view illustrating a configuration example of a substrate with a built-in functional element according to a first exemplary embodiment.

FIG. 2 is an outline cross-sectional view illustrating a configuration example of the substrate with a built-in functional element according to the first exemplary embodiment.

FIG. 3 are outline cross-sectional views each illustrating a configuration example of the substrate with a built-in functional element according to the first exemplary embodiment.

FIG. 4 is an outline cross-sectional view illustrating a configuration example of the substrate with a built-in functional element according to the first exemplary embodiment.

FIG. 5 is an outline cross-sectional view illustrating a configuration example of a substrate with a built-in functional element according to a second exemplary embodiment.

FIG. 6 is an outline cross-sectional view illustrating a configuration example of the substrate with a built-in functional element according to the second exemplary embodiment.

FIG. 7 is an outline cross-sectional view illustrating a configuration example of the substrate with a built-in functional element according to the second exemplary embodiment.

FIG. 8 is an outline cross-sectional view illustrating a configuration example of the substrate with a built-in functional element according to the second exemplary embodiment.

FIG. 9 is an outline cross-sectional view illustrating a configuration example of the substrate with a built-in functional element according to the second exemplary embodiment.

FIG. 10 is an outline cross-sectional view illustrating a configuration example of the substrate with a built-in functional element according to the second exemplary embodiment.

FIG. 11 are outline cross-sectional views each illustrating a configuration example of the substrate with a built-in functional element according to the second exemplary embodiment.

FIG. 12 is an outline cross-sectional view illustrating a configuration example of the substrate with a built-in functional element according to the second exemplary embodiment.

FIG. 13 are cross-sectional step views for describing steps of manufacturing the substrate with a built-in functional element of the first exemplary embodiment illustrated in FIG. 1.

FIG. 14 are cross-sectional step views for describing steps of manufacturing the substrate with a built-in functional element of the second exemplary embodiment illustrated in FIG. 5.

FIG. 15 is an outline view of horizontal cross-section taken along an arrow A in the substrate with a built-in functional element illustrated in FIG. 1.

FIG. 16 is an outline view of horizontal cross-section taken along an arrow B in the substrate with a built-in functional element illustrated in FIG. 1.

FIG. 17 is an outline view of horizontal cross-section taken along an arrow C in the substrate with a built-in functional element illustrated in FIG. 1.

FIG. 18 is an outline view of horizontal cross-section taken along an arrow D in the substrate with a built-in functional element illustrated in FIG. 1.

FIG. 19 is an outline view of horizontal cross-section taken along an arrow E in the substrate with a built-in functional element illustrated in FIG. 4.

FIG. 20 is an outline cross-sectional view illustrating a configuration example of a conventional substrate with a built-in functional element.

### DESCRIPTION OF EMBODIMENTS

The present invention is described below.

### First Exemplary Embodiment

A first invention of the present invention is described below by way of an exemplary embodiment.

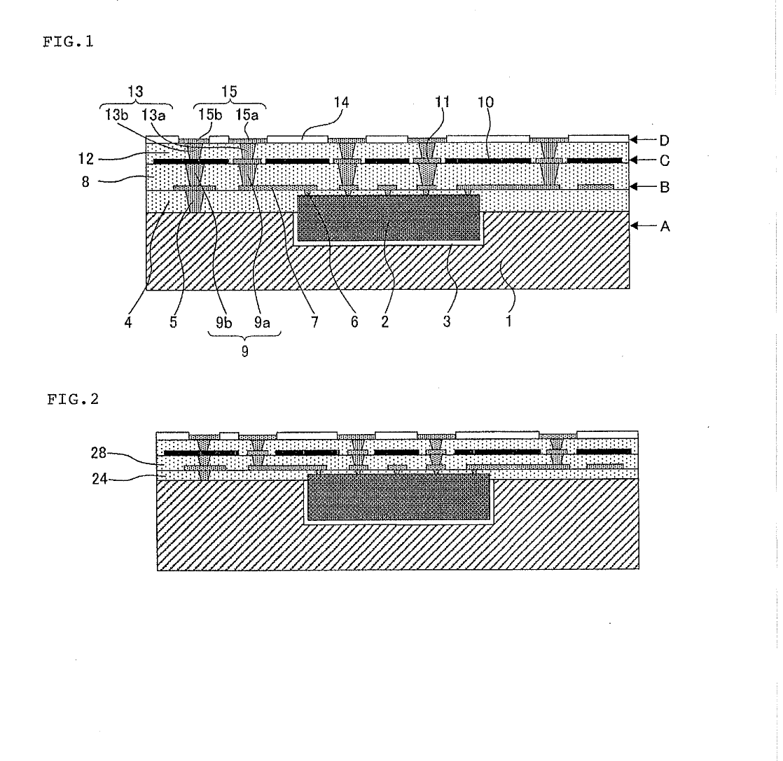

FIG. 1 illustrates a configuration example of a substrate with a built-in functional element according to the present exemplary embodiment. FIG. 1 is an outline cross-sectional view schematically illustrating a structure of the substrate with a built-in functional element according to the present exemplary embodiment.

In FIG. 1, a metal plate 1 that functions as a ground and a support is provided with a concave portion, and a functional element 2 such as a semiconductor chip is placed in the concave portion with the intermediation of an adhesive agent 3. The functional element 2 includes electrode terminals (not illustrated) on a circuit-side (the upper side of FIG. 1) surface thereof, and is placed above the metal plate 1 with the circuit surface thereof facing upward. The metal plate 1 supports the functional element 2, and is bonded to a rear-side (the lower side of FIG. 1) surface of the functional element 2 with the intermediation of the adhesive layer 3. The functional element 2 is covered by a first insulating layer 4, and is built in the concave portion of the metal plate 1 and the first insulating layer 4. A first wiring layer including first signal wiring 7 is provided on the first insulating layer 4, and element vias 6 that electrically connect the first signal wiring 7 to the functional element 2 are provided in the first insulating layer 4.

The first wiring layer is a wiring layer mainly including the first signal wiring 7. The first signal wiring is provided on the element vias that are in contact with the respective electrode terminals of the functional element, functions to deal with input/output signals to/from the functional element, and spreads in the in-plane direction. Accordingly, the first signal wiring 7 is opposite the metal plate 1 with the first insulating layer 4 being interposed therebetween. The first wiring layer can also include power supply wiring in addition to the first signal wiring.

The first wiring layer is covered by a second insulating layer 8, and a ground layer 10 and a second wiring layer are provided on the second insulating layer 8. The ground layer 10 is formed of a ground plane that is ground wiring with a solid pattern, and the second wiring layer includes second signal wiring 11. The ground layer 10 is provided over substantially the entire surface of the second insulating layer 8 except for the region in which the second wiring layer is provided. In addition, second layer vias 9 are provided in the second insulating layer 8, and in FIG. 1, the second layer vias 9 include second layer signal vias 9a and a second layer ground via 9b. The second layer signal vias 9a are vias that electrically connect the second signal wiring 11 to the first signal wiring 7. In addition, in the present invention, the metal plate 1 also functions as the ground. In FIG. 1, a first layer via 5 as a ground via is provided in the first insulating layer 4, and the ground layer 10 and the metal plate 1 are electrically connected to each other with the intermediation of at least the first layer via 5 and the second layer ground via 9b, and form a ground with the same potential.

In the present invention, the first signal wiring 7 is placed between the metal plate 1 serving as the ground and the ground layer 10. In addition, in the present invention, the metal plate 1 is provided with the concave portion, and the functional element 2 is placed in the concave portion. Because the metal plate 1 is provided with the concave portion, in which the functional element is placed, the distance between the metal plate 1 and the first signal wiring 7 can be adjusted by the depth of the concave portion. Accordingly, the electrostatic capacitance between the metal plate 1 serving as ground and the first signal wiring 7 can be adjusted, and the characteristic impedance matching of the first signal wiring 7 can be achieved. That is, conventionally, a ground layer is provided in a wiring substrate, whereby characteristic impedance matching is achieved. In contrast, in the present invention, the metal plate is provided with the concave portion and serves as the ground, whereby the characteristic impedance matching of the first signal wiring can be achieved with the effective use of the metal plate. In addition, the area of the ground layer provided in the substrate can be reduced while the level of the characteristic impedance matching of the first signal wiring is maintained. Further, in the present invention, the depth of the concave portion is adjusted such that the metal plate 1 serving as the ground, the first signal wiring 7, and the ground layer 10 form a stripline structure, whereby higher characteristic impedance matching can be achieved. For example, the characteristic impedance can be matched to about 50Ω by adjusting the depth of the concave portion.

In the present invention, the distance between the first signal wiring 7 and the metal plate 1 can be controlled on the basis of the shape of the concave portion. For example, as illustrated in FIG. 2, if the concave portion is formed more deeply than that in FIG. 1, the thickness of a first insulating layer 24, that is, the distance between the first signal wiring 7 and the metal plate 1 can be made smaller than that in FIG. 1. In addition, in FIG. 2, if a second insulating layer 28, the thickness of which is adjusted, is formed, the distance between the ground layer 10 and the first signal wiring 7 can be made substantially equal to the distance between the first signal wiring 7 and the metal plate 1, so that the stripline structure is formed more easily. Accordingly, the present invention enables the adjustment of the distance between the metal plate 1 and the first signal wiring 7, and thus is particularly advantageous when the functional element is thick. Note that the distance between the metal plate 1 and the first signal wiring 7 refers to the shortest distance between a metal plate plane portion of the region other than the concave portion and the first signal wiring 7 in FIG. 1. In addition, the distance between the first signal wiring 7 and the ground layer 10 refers to the shortest distance between the upper surface of the first signal wiring 7 and the lower surface of the ground layer 10.

In FIG. 1, the ground layer 10 is placed so as to surround the second signal wiring 11, and is formed into a planar plate-like pattern that spreads over substantially the entire surface of the second insulating layer 8. The second signal wiring 11 of the second wiring layer is mainly formed of lands that each connect vias placed on the top and bottom thereof, but the present invention is not particularly limited thereto, and the second signal wiring 11 may include a wiring line portion. Particularly in the present invention, because the metal plate 1 functions as the ground, the characteristic impedance matching of the first signal wiring 7 can be effectively achieved using the metal plate. Hence, a placement region of the ground layer 10 can be reduced, and the second signal wiring 11 including the wiring line portion can be provided accordingly.

Further, in FIG. 1, a third insulating layer 12 is provided so as to cover the ground layer 10 and the second wiring layer including the second signal wiring 11. A solder mask 14 is provided on the third insulating layer 12. The solder mask 14 is provided with external connection terminals 15 that are used for connection with an external substrate and the like. In addition, third layer vias 13 are provided in the third insulating layer 12, and the third layer vias 13 include third layer signal vias 13a and a third layer ground via 13b. The third layer signal vias 13a are in contact with the second signal wiring 11, and the third layer ground via is in contact with the ground layer 10. In addition, the external connection terminals 15 include signal terminals 15a and a ground terminal 15b. The signal terminals 15a are in contact with the respective third layer signal vias 13a, and the ground terminal 15b is in contact with the third layer ground via 13b. For example, BGA balls are placed as the external connection terminals, and the external connection terminals are connected to the external substrate.

Furthermore, in FIG. 1, the external connection terminals 15 may have a construction such that signal wiring or ground wiring are exposed in the solder mask 14. That is, ground wiring and a third wiring layer including third signal wiring can be provided on the third insulating layer 12, and the solder mask 14 can be formed on the ground wiring and the third signal wiring such that parts of the ground wiring and the third signal wiring are exposed. In addition, the external connection terminals can, for example, protect the surface so as to prevent an outflow of solder.

Examples of the functional element include an active component such as a semiconductor chip and a passive component such as a capacitor. Examples of the semiconductor chip include a transistor, an IC, and an LSI. For example, a complementary metal oxide semiconductor (CMOS), to which the present invention is not particularly limited, can be selected as the semiconductor chip.

Note that the thickness of the functional element is, for example, 50 to 100 μm in the case of a semiconductor chip. The thickness thereof is, for example, 200 to 400 μm in the case of a chip-type passive component. In addition, the thickness thereof is, for example, 100 to 200 μm in the case of a thin-film passive component.

The number of the functional elements provided in the substrate with a built-in functional element is one or more. In the case where the number of the provided functional elements is more than one, it is preferable to build one functional element in one concave portion, but the present invention is not particularly limited thereto, and a plurality of functional elements may be arranged and built in one concave portion.

A conductor used for the wiring layer, the ground layer, and the via is not particularly limited, and examples of the conductor that is used include: metal containing at least one type selected from the group consisting of copper, silver, gold, nickel, aluminum, and palladium; and an alloy containing these metals as its main components. Among these metals, Cu is preferably used as the conductor from the viewpoint of electrical resistance and costs.

In addition, the material of the via is not particularly limited as long as the material is conductive. In addition to the above-mentioned metals, examples of the material thereof include: a soldering material; and a conductive resin paste containing thermo-setting resin and conductive metal powder of copper, silver, or the like. It is preferable that the conductive resin paste be a paste material containing nanoparticles as conductive particles. In addition, it is more preferable that the conductive resin paste be a material containing a volatile resin component or a material containing a resin component that sublimates while the material is heated to form a sintered body. It is further preferable that the via be formed according to a deposition method, a sputtering method, a chemical vapor deposition (CVD) method, an atomic layer deposition (ALD) method, an electroless plating method, an electroplating method, or the like, which provides stable stiffness. An example method of manufacturing the via involves: forming a power feeding layer according to the deposition method, the sputtering method, the CVD method, the ALD method, the electroless plating method, or the like; and then adjusting the thickness of the power feeding layer to a desired thickness according to the electroplating method or the electroless plating method. In addition, a preferable opening diameter of the via is approximately as large as the via film thickness, but the present invention is not limited thereto. The aspect ratio of the via height to the via diameter is set to preferably 0.3 or more and 3 or less, is set to more preferably 0.5 or more and 1.5 or less, and is set to further preferably about 1.

The thickness of the first signal wiring is, for example, 3 to 40 μm. In addition, the thickness thereof is set to preferably 15 to 20 μm from the viewpoint that the characteristic impedance of the signal wiring is matched to 50Ω more easily. In addition, it is desirable that the width of a wiring line portion of the first signal wiring be set as appropriate taking into consideration the relative permittivity of the first and second insulating layers. In addition, it is preferable that the width of the wiring line portion of the first signal wiring be substantially uniform over the entire first wiring layer, from the viewpoint of characteristic impedance matching. In addition, it is desirable that the line width and space width of the first wiring layer be equivalent to or more than the wiring thickness, but the present invention is not limited thereto.

The material of the metal plate is not particularly limited, and examples of the used material thereof include: metal containing at least one type selected from the group consisting of copper, silver, gold, nickel, aluminum, and palladium; and an alloy containing these metals as its main components. Among these metals, copper is preferably used as the material of the metal plate from the viewpoint of electrical resistance and cost.

In addition, the metal plate also functions as an electromagnetic shield, and thus is expected to reduce unnecessary electromagnetic radiation.

In addition, a via land formed of a metal layer may be provided on the metal plate 1. In this case, adhesion force between the first layer via 5 provided in the first insulating layer 4 and the metal plate 1 can be improved.

Further, a surface of the metal plate 1 opposite to the surface on which the concave portion is provided is planar, and hence a heat sink and other components may be provided on this opposite surface.

The material of the insulating layer is an insulating resin, and an insulator similar to that used for a normal wiring substrate can be used as the material thereof. Examples of the material of the insulating layer that is used include organic materials such as epoxy resin, epoxy acrylate resin, urethane acrylate resin, polyester resin, phenolic resin, polyimide resin, and polynorbornene resin. Examples of the material that is used thereof also include benzocyclobutene (BCB) and polybenzoxazole (PBO). Among these materials, polyimide resin and PBO have excellent mechanical characteristics such as film strength, modulus of tensile elasticity, and a coefficient of breaking elongation, and thus can provide high reliability. The material of the insulating layer may be photosensitive or may be non-photosensitive. In addition, the insulating layer may contain glass cloth or aramid non-woven fabric.

A different insulating material may be used for each insulating layer, and the same insulating material may be used for all the insulating layers.

In addition, the configuration illustrated in FIG. 1 or 2 includes the three insulating layers and the solder mask as the outermost layer, but the present invention is not particularly limited to this configuration, and is not limited to the number of layers illustrated in the drawings and the exemplary embodiments.

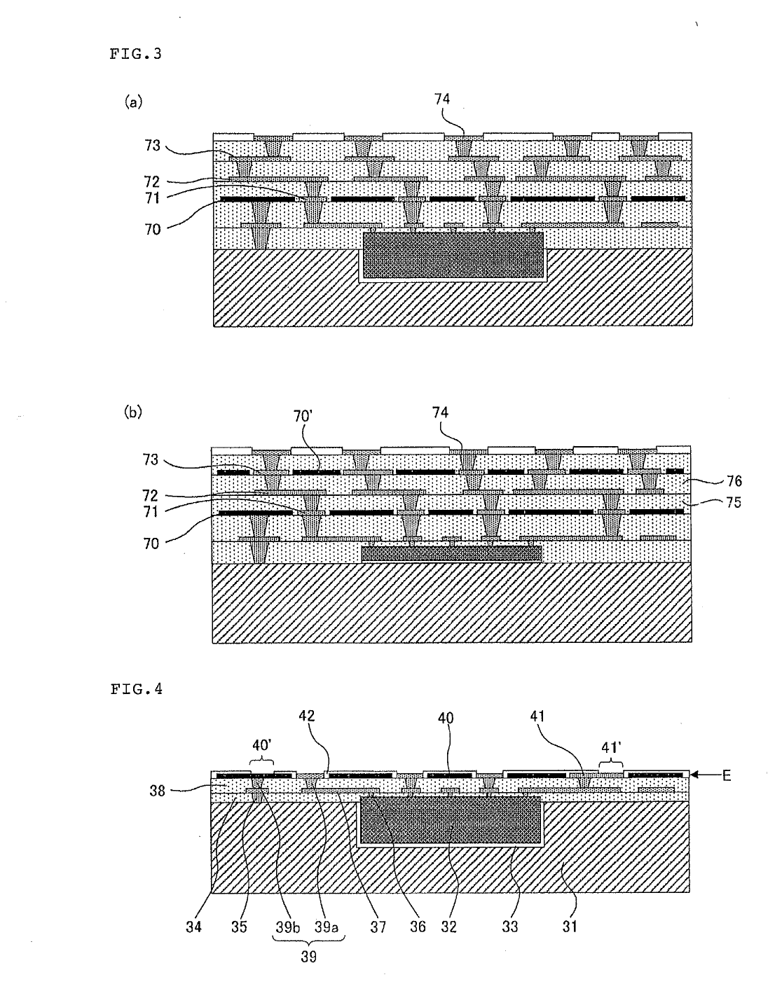

In addition, as illustrated in FIG. 3, one or more wiring layers can be further provided in upper layer(s) of a ground layer 70 and a second wiring layer including first signal wiring 71. That is, other wiring layer(s) can be further provided on the outer side of the ground layer. For example, as illustrated in FIG. 3(a), a third wiring layer including third signal wiring 72 and a fourth wiring layer including fourth signal wiring 73 can be provided, and external connection terminals 74 can be provided thereabove. In addition, each wiring layer can be sandwiched between ground layers that are respectively provided in upper and lower layers of the wiring layer. For example, as illustrated in FIG. 3(b), the third wiring layer including the third signal wiring 72 can be sandwiched between the ground layers 70 and 70′. That is, a third insulating layer 75 is formed so as to cover the second signal wiring 71 and the first ground layer 70, and the third wiring layer including the third signal wiring 72 is formed on the third insulating layer 75. A fourth insulating layer 76 is formed so as to cover the third wiring layer, and the second ground layer 70′ and the fourth wiring layer including the fourth signal wiring 73 are formed on the fourth insulating layer 76. The second ground layer 70′ is formed over substantially the entire surface of the fourth insulating layer 76 except for the region in which the fourth wiring layer is formed.

In addition, in FIG. 1 or 2, the first signal wiring 7 is electrically connected to the electrode terminals of the functional element through the element vias 6, but the present invention is not particularly limited thereto, and post electrodes provided on the respective electrode terminals can be used instead of the element vias.

In addition, although the external connection terminals and the solder mask can be formed so as to be level with each other, in FIG. 1, the external connection terminals 15 are formed so as to be lower than the solder mask 14. In the case where the surfaces of the external connection terminals 15 are lower than that of the solder mask 14, solder balls and the like are advantageously formed on this surface. Alternatively, the external connection terminals 15 may be formed so as to be higher than the solder mask 14.

The external connection terminal can be formed using, for example, metal of at least one type selected from the group consisting of gold, silver, copper, tin, and a solder material or an alloy thereof. The external connection terminal can be formed by laminating, for example, nickel with a thickness of 3 μm and gold with a thickness of 0.5 μm in the stated order. The pitch of the external connection terminals is, for example, 50 to 1,000 μm, and more preferably 50 to 500 μm.

In addition, FIG. 4 illustrates the present exemplary embodiment taken from the viewpoint of a reduction in thickness.

In FIG. 4, a metal plate 31 that functions as a ground and a support is provided with a concave portion, and a functional element 32 such as a semiconductor chip is placed in the concave portion with the intermediation of an adhesive agent 33. The functional element 32 includes electrode terminals (not illustrated) on a circuit-side (the upper side of FIG. 4) surface thereof, and is placed above the metal plate 31 with the circuit surface thereof facing upward. The metal plate 31 supports the functional element 32, and is bonded to a rear-side (the lower side of FIG. 4) surface of the functional element 32 with the intermediation of the adhesive layer 33. The functional element 32 is covered by a first insulating layer 34, and is built in the concave portion of the metal plate 31 and the first insulating layer 34. A first wiring layer including first signal wiring 37 is provided on the first insulating layer 34, and element vias 36 that electrically connect the first signal wiring 37 to the functional element 32 are provided in the first insulating layer 34. The first signal wiring 37 functions to deal with input/output signals to/from the functional element, and spreads in the in-plane direction on the first insulating layer 34.

The first wiring layer is covered by a second insulating layer 38, and a ground layer 40 and a second wiring layer are provided on the second insulating layer 38. The ground layer 40 is formed of a ground plane that is ground wiring with a solid pattern, and the second wiring layer includes second signal wiring 41. The ground layer 40 is provided over substantially the entire surface of the second insulating layer 38 except for the region in which the second wiring layer is provided. In addition, second layer vias 39 are provided in the second insulating layer 38, and in FIG. 4, the second layer vias 39 include second layer signal vias 39a and a second layer ground via 39b. The second layer signal vias 39a are vias that electrically connect the second signal wiring 41 to the first signal wiring 37. In addition, in the present invention, the metal plate 31 also functions as the ground. In FIG. 4, a first layer via 35 as a ground via is provided in the first insulating layer 34, and the ground layer 40 and the metal plate 31 are electrically connected to each other with the intermediation of at least the first layer via 35 and the second layer ground via 39b, and form a ground with the same potential.

In addition, a third insulating layer 42 is provided so as to cover the ground layer 40 and the second signal wiring 41. The third insulating layer 42 is, for example, a solder mask. In addition, in FIG. 4, external connection terminals are formed by opening the third insulating layer 42 so as to expose parts of the second wiring layer and the ground layer 40. For example, the third insulating layer 42 is placed on the second wiring layer and the ground layer 40, and the third insulating layer 42 is etched such that parts of the second wiring layer and the ground layer 40 are exposed, whereby the external connection terminals can be formed. In FIG. 4, 40′ denotes a portion in which part of the ground layer 40 is exposed on the third insulating layer 42, and the portion forms a ground terminal. 41′ denotes a portion in which part of the second wiring layer is exposed on the third insulating layer 42, and the portion forms a signal terminal and a power supply terminal. For example, BGA balls are placed as the external connection terminals, and the external connection terminals are connected to the external substrate. In addition, the external connection terminals can, for example, protect the surface so as to prevent an outflow of solder.

Now, a principle for characteristic impedance matching is described. In most cases, the signal wiring of the functional element is designed to have a characteristic impedance matched to 50Ω, and hence the wiring substrate connected to the functional element is also designed to have a characteristic impedance matched to 50Ω. In the present invention, as described above, the metal plate provided with the concave portion is used as the ground, and the distance between the metal plate and the first signal wiring is adjusted by the depth of the concave portion, whereby the characteristic impedance matching of the first signal wiring can be achieved. At this time, it is preferable that the metal plate serving as the ground, the signal wiring and the ground plane form a stripline structure. This is because the stripline structure is excellent in wiring housing, and enables relatively easy characteristic impedance matching. In addition, because the signal wiring is sandwiched between the grounds, the resistance to external noise is improved. The characteristic impedance matching can be achieved by changing the line width, the thickness of the insulating layer, and the permittivity of the insulating layer.

In order to obtain an effect as the stripline structure, it is desirable that the two insulating layers that are placed so as to sandwich the signal wiring from above and below be made of the same material and that the distance from the signal wiring to the metal plate that serves as the ground be equal to the distance from the signal wiring to the ground layer. Taking the above into consideration, in the present invention, it is preferable that the same material be used for the first insulating layer and the second insulating layer and that the metal plate be provided with the concave portion such that the distance from the signal wiring to the metal plate serving as the ground is equal to the distance from the signal wiring to the ground layer.

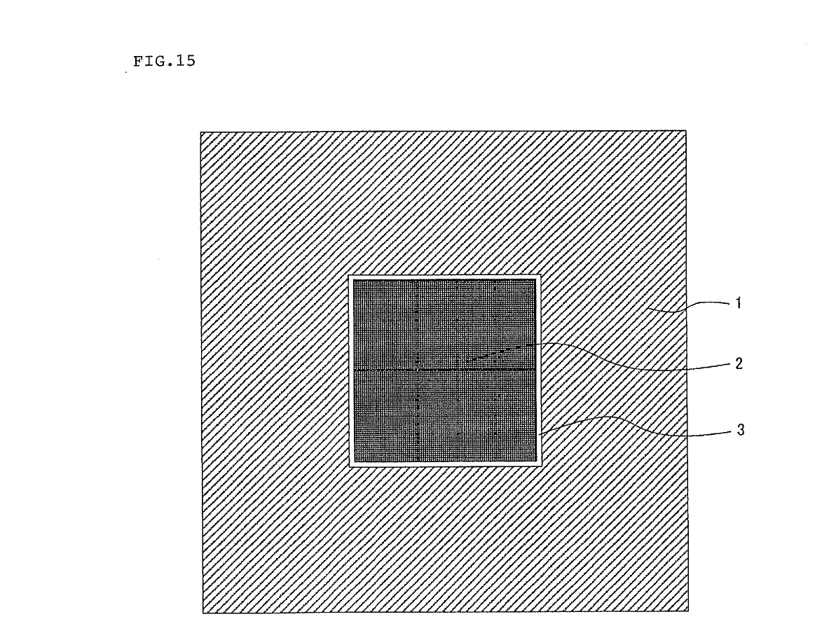

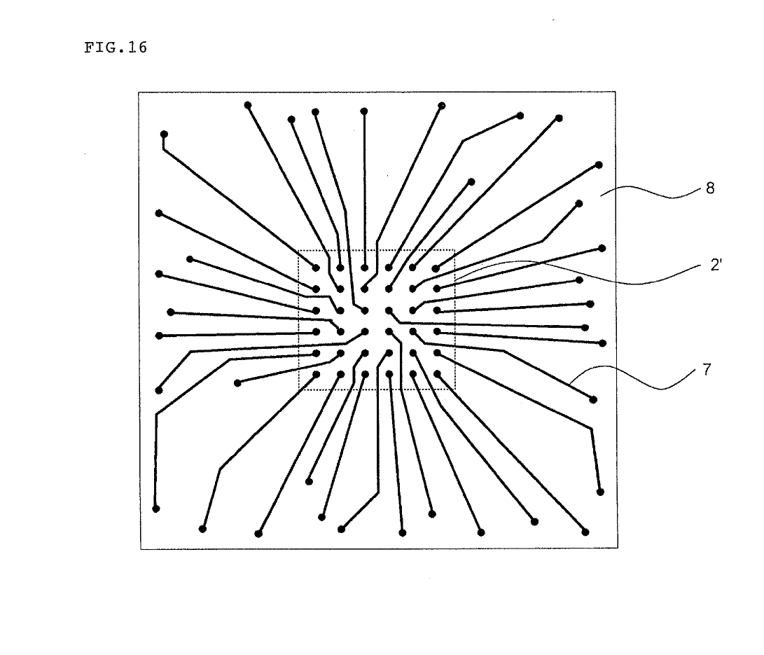

FIGS. 15 to 18 respectively illustrate example cross-sectional views in the horizontal direction (hereinafter, abbreviated as horizontal cross-sectional views) that are taken along arrows A, B, C, and D illustrated in FIG. 1 according to the present exemplary embodiment. In addition, FIG. 19 illustrates a horizontal cross-sectional view taken along an arrow E illustrated in FIG. 4. In FIGS. 16 to 19, a dotted line 2′ indicates a placement position of the functional element.

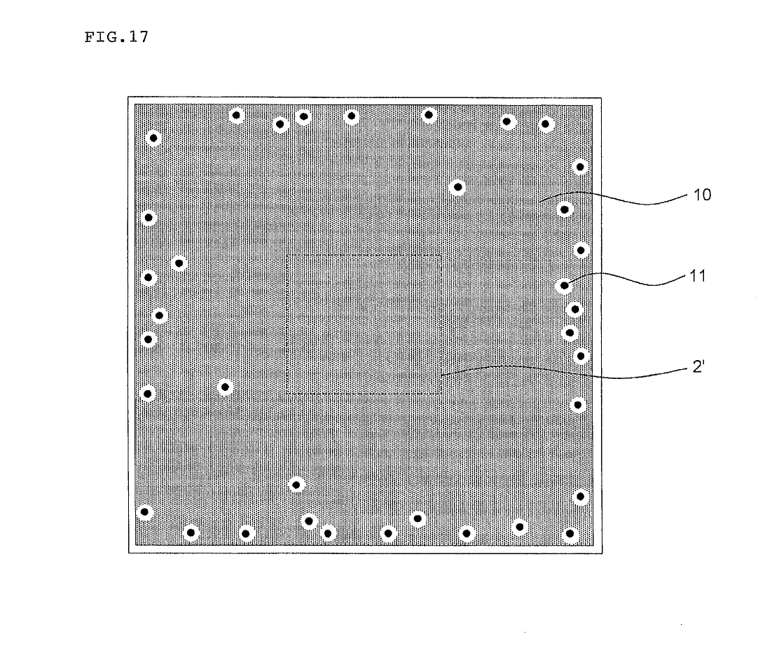

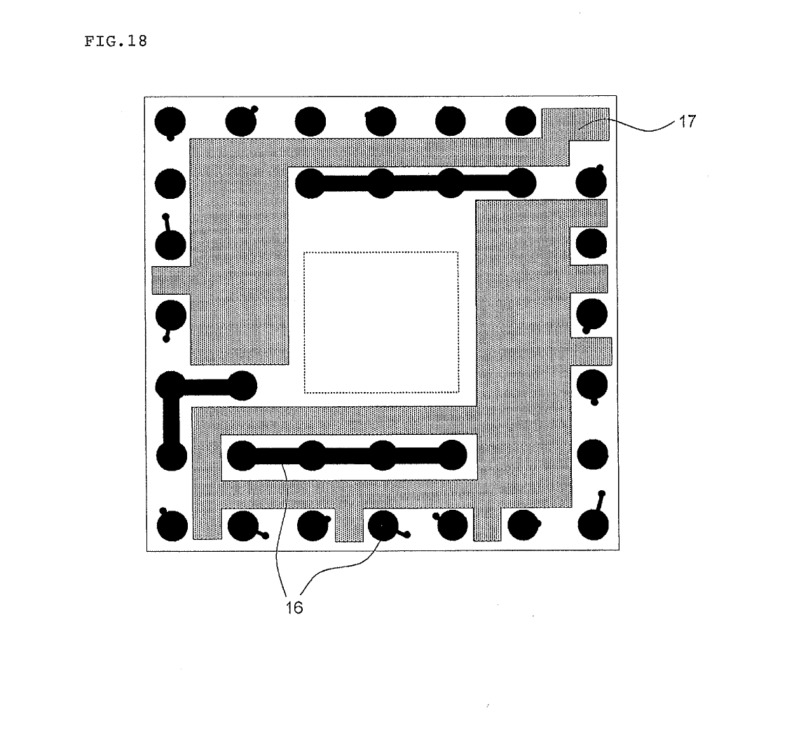

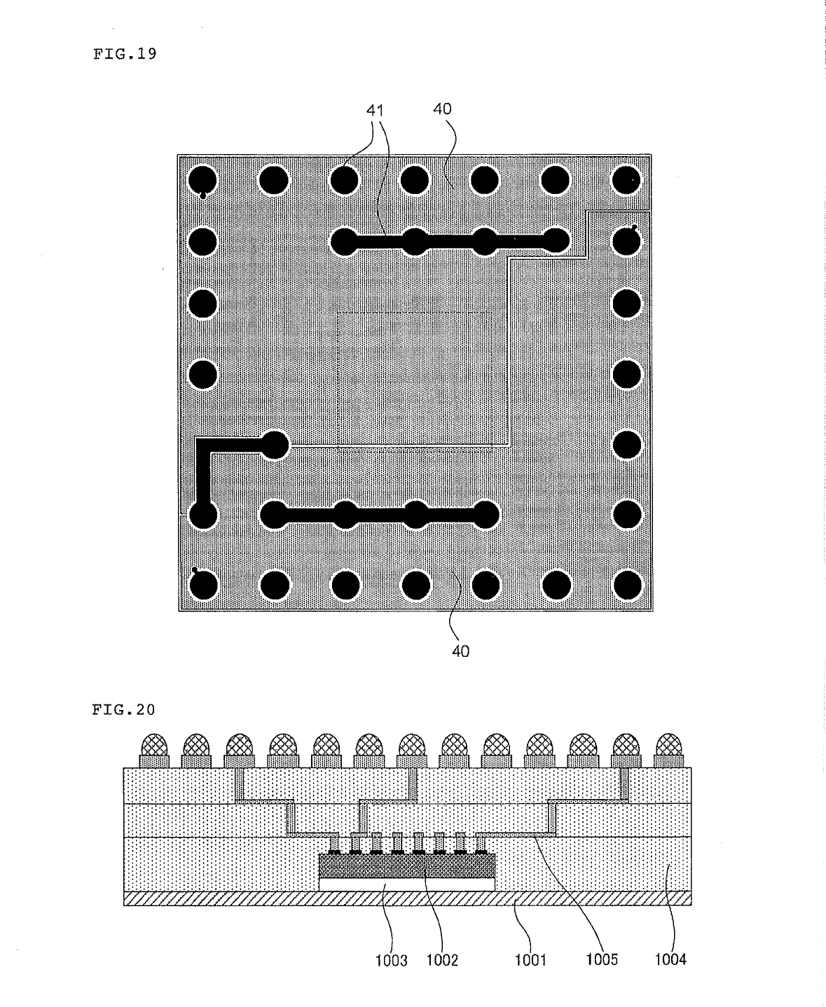

As illustrated in FIG. 16 that is the horizontal cross-sectional view taken along the arrow B in FIG. 1, the first signal wiring 7 includes lands and the wiring line portion, and spreads in the in-plane direction. As illustrated in FIG. 17 that is the horizontal cross-sectional view taken along the arrow C in FIG. 1, the ground layer 10 is formed of the ground plane that is the ground wiring with the solid pattern, and is provided over substantially the entire surface of the second insulating layer except for the region in which the second wiring layer is provided. As illustrated in FIG. 18 that is the horizontal cross-sectional view taken along the arrow D in FIG. 1, signal wiring 16 (indicated in black) and a ground layer 17 are formed within the solder mask 14 as the uppermost layer. The solder mask 14 is opened such that the signal wiring 16 and the ground layer 17 within the solder mask 14 are exposed, whereby the external connection terminals can be formed.

As illustrated in FIG. 19 that is the horizontal cross-sectional view taken along the arrow E in FIG. 4, the signal wiring 41 (indicated in black) and the ground layer 40 are formed within the solder mask 42 as the uppermost layer. The solder mask 42 is opened such that the signal wiring 41 and the ground layer 40 within the solder mask 42 are exposed, whereby the external connection terminals such as the signal terminal 41′ and the ground terminal 40′ can be formed.

Note that these horizontal cross-sectional views are given as mere examples, and thus put no limitation on the present invention.

In the present exemplary embodiment, for example, in the case where a semiconductor chip with a thickness of 50 μm is used, the stripline structure is formed under the conditions in which: the depth of the concave portion is 20 μm; the thickness of the adhesive agent 3 between the semiconductor chip and a copper plate is 5 μm; the thickness of the first insulating layer is 35 μm; the thickness of the second insulating layer is 35 μm; the width and height of the first signal wiring are 20 μm and 10 μm, respectively; and the first insulating layer and the second insulating layer are made of the same material and have a relative permittivity of about 4. As a result, the characteristic impedance can be matched to about 50 Ω.

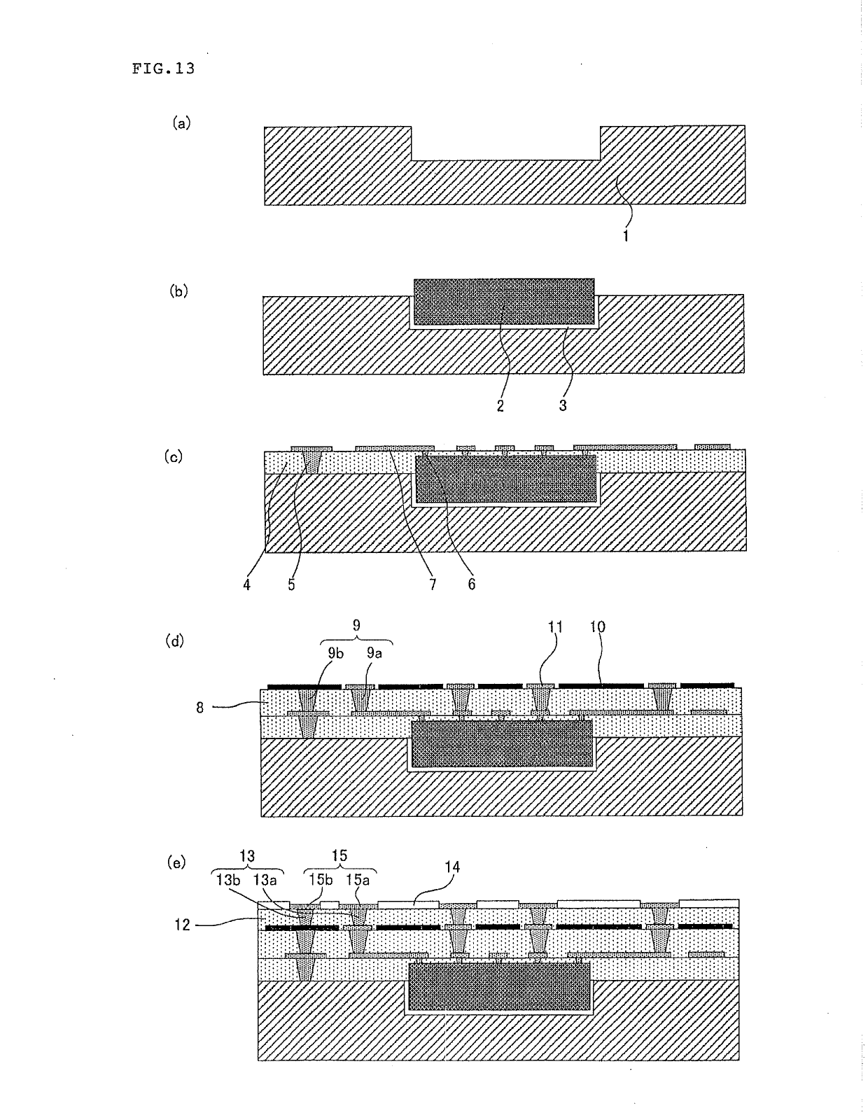

Next, a method of manufacturing the substrate with a built-in functional element according to the present invention is described with reference to FIG. 13. FIG. 13 are cross-sectional step views schematically illustrating steps of manufacturing the substrate with a built-in functional element according to the present invention. A semiconductor chip is used as the functional element in the following description. In addition, the present invention is not limited to the following method of manufacturing.

First, as illustrated in FIG. 13(a), the metal plate 1 including the concave portion is prepared.

Note that the metal plate 1 can be provided with a position mark for mounting the semiconductor chip 2. Examples of the method of forming the position mark include: a method of depositing metal on the metal plate 1; and a method of forming a recess by wet etching or mechanical processing.

Next, as illustrated in FIG. 13(b), the semiconductor chip 2 is mounted onto the concave portion of the metal plate 1 with the intermediation of the adhesive agent 3 with the electrode terminals (not illustrated) facing upward.

Examples of the used adhesive agent include epoxy resin, epoxy acrylate resin, urethane acrylate resin, polyester resin, phenolic resin, and polyimide resin.

Next, as illustrated in FIG. 13(c), the first insulating layer 4, the first layer via 5, the element vias 6, and the first wiring layer including the first signal wiring 7 are formed. More specifically, the first insulating layer 4 is formed on the metal plate 1 so as to cover the electrode terminal-side surface of the semiconductor chip 2 and part of the side walls thereof. In addition, the element vias 6 connected to the respective electrode terminals and the first layer via 5 connected to the metal plate 1 are formed in the first insulating layer 4. In addition, as illustrated in FIG. 13(c), the first wiring layer including the first signal wiring 7 is formed on the first insulating layer 4 including the element vias 6 and the first layer via 5.

Examples of the method of forming the first insulating layer include a transfer molding method, a compression molding method, a printing method, vacuum pressing, vacuum lamination, a spin coating method, a die coating method, and a curtain coating method.

In the case where the first insulating layer 4 is made of a photosensitive material, base holes for the vias can be formed according to a photolithographic method. In the case where the first insulating layer 4 is made of a non-photosensitive material or a material with a low pattern resolution, the base holes for the vias can be formed according a laser processing method, a dry etching method, or a blasting method.

In addition, examples of the method of forming the vias include electroplating, electroless plating, a printing method, and a molten metal suctioning method.

In addition, the element vias that are connected to the respective electrode terminals of the semiconductor chip may be formed in the following manner. That is, a metal post for electrical conduction is provided in advance on each electrode terminal, the material of the first insulating layer 4 is placed thereon, the surface of the insulating material is then ground by polishing or the like, and the surface of the metal post is thus exposed, whereby each element via is formed. In this case, after the formation of the first layer via 5, the surface of the first insulating layer may be ground, and the surface of the metal post may be thus exposed. Alternatively, after the grinding of the material surface of the first insulating layer and the exposure of the surface of the metal post, the first layer via 5 may be formed. Examples of the grinding method include buffing and CMP.

Wiring including signal wiring and electrode wiring can be formed according to, for example, a subtractive method, a semi-additive method, and a full-additive method, with the use of, for example, metal such as Cu, Ni, Sn, or Au.

The subtractive method is disclosed in, for example, JP10-51105A. The subtractive method involves: etching copper foil using a resist as an etching mask, the copper foil being provided on a substrate or resin, the resist being formed into a desired pattern; removing the resist after the etching; and thus obtaining a desired wiring pattern.

The semi-additive method is disclosed in, for example, JP09-64493A. The semi-additive method involves: forming a power feeding layer; then forming a resist into a desired pattern; depositing electroplating in an opening portion of the resist; removing the resist; then etching the power feeding layer; and thus obtaining a desired wiring pattern. The power feeding layer can be formed according to, for example, electroless plating, a sputtering method, and a CVD method.

The full-additive method is disclosed in, for example, JP06-334334A. The full-additive method involves: adsorbing an electroless plating catalyst onto the surface of a substrate or resin; forming a pattern using a resist; then activating the catalyst with the resist being held as an insulating layer; depositing metal in an opening portion of the insulating layer according to an electroless plating method; and thus obtaining a desired wiring pattern.

Next, as illustrated in FIG. 13(d), the second insulating layer 8, the second layer vias 9, the ground layer 10, and the second wiring layer including the second signal wiring 11 are formed. More specifically, the second insulating layer 8 is formed so as to cover the first wiring layer including the first signal wiring 7, and the second layer vias 9 are formed in the second insulating layer 8. In addition, the ground layer 10 and the second wiring layer including the second signal wiring 11 are formed on the second insulating layer 8.

The ground layer can be obtained, for example, by: forming a metal film according to a sputtering method, a vacuum deposition method, or a plating method; and then forming the metal film into a predetermined shape according to a photolithographic method.

Next, as illustrated in FIG. 13(e), the third insulating layer 12, the third layer vias 13, the solder mask 14, and the external connection terminals 15 are formed. More specifically, the third insulating layer 12 is formed so as to cover the second wiring layer including the second signal wiring 11 and the ground layer 10, and the third layer vias 13 are formed in the third insulating layer 12. In addition, the external connection terminals 15 and the solder mask 14 are formed on the third insulating layer 12.

The external connection terminals 15 may also function as signal wiring and ground wiring. In this case, the solder mask is etched such that parts of the signal wiring and the ground wiring are exposed, whereby the external connection terminals can be formed.

Next, specific sizes and materials are described below by way of an example.

First, as illustrated in FIG. 13(a), the metal plate 1 including the concave portion was prepared. A copper plate with a thickness of 0.5 mm was used for the metal plate 1, and the depth, length, and width of the concave portion were respectively set to 20 μm, 10 mm, and 10 mm.

Next, as illustrated in FIG. 13(b), the semiconductor chip 2 was mounted into the concave portion of the metal plate 1 with the intermediation of the adhesive agent 3 with the electrode terminals (not illustrated) facing upward. An LSI chip with a thickness of 50 μm, a length of 9.5 mm, and a width of 9.5 mm was used for the semiconductor chip 2. An epoxy-based adhesive was used for the adhesive agent, and the thickness of the adhesive agent was set to 5 μm.

Next, as illustrated in FIG. 13(c), the first insulating layer 4, the first layer via 5, the element vias 6, and the first wiring layer including the first signal wiring 7 were formed. Epoxy resin was used for the first insulating layer 4, and the first insulating layer 4 was formed according to a vacuum lamination method so as to have a thickness of 35 μm. The first wiring layer was formed according to a semi-additive method using Cu so as to have a thickness of 10 μm and a width of 20 μm. In addition, the line width and space width of the first wiring layer were set to be equal to or more than the wiring thickness.

Next, as illustrated in FIG. 13(d), the second insulating layer 8, the second layer vias 9, the ground layer 10, and the second wiring layer including the second signal wiring 11 were formed. Epoxy resin was used for the second insulating layer 8, and the second insulating layer 8 was formed according to a vacuum lamination method so as to have a thickness of 35 μm. The second wiring layer and the ground layer were each formed according to a subtractive method using Cu so as to have a thickness of 15 μm. In addition, the line width and space width of the second wiring layer were set to be equal to or more than the wiring thickness. A ground plane was formed as the ground layer over substantially the entire surface of the second insulating layer 8 except for the region in which the second wiring layer was provided.

Next, as illustrated in FIG. 13(e), the third insulating layer 12, the third layer vias 13, the solder mask 14, and the external connection terminals 15 were formed. Epoxy resin was used for the third insulating layer 12, and the third insulating layer 12 was formed according to a vacuum lamination method so as to have a thickness of 35 μm.

### Second Exemplary Embodiment

A second invention of the present invention is described below by way of an exemplary embodiment.

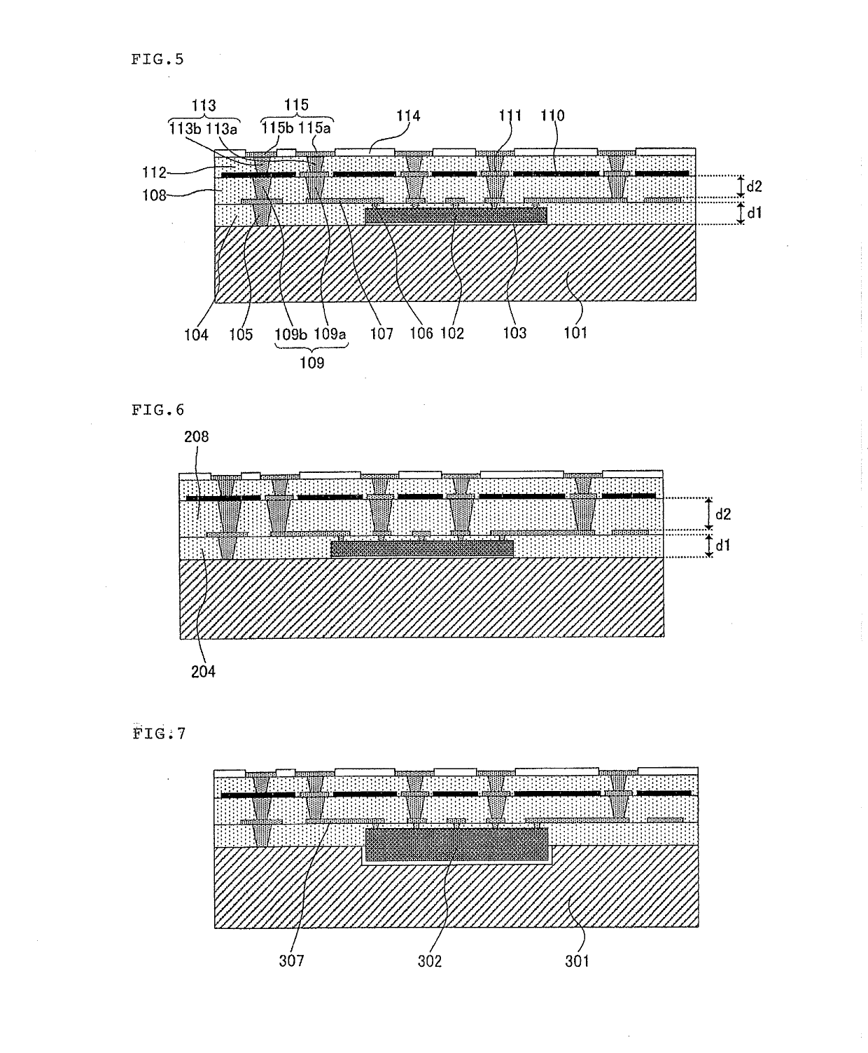

FIG. 5 illustrates a configuration example of a substrate with a built-in functional element according to the present exemplary embodiment. FIG. 5 is an outline cross-sectional view schematically illustrating a structure of the substrate with a built-in functional element according to the present exemplary embodiment. In FIG. 5, a functional element 102 such as a semiconductor chip is provided above a metal plate 101 that functions as a ground and a support, with the intermediation of an adhesive agent 103. The functional element 102 includes electrode terminals (not illustrated) on a circuit-side (the upper side of FIG. 5) surface thereof, and is placed above the metal plate 101 with the circuit surface thereof facing upward. The metal plate 101 supports the functional element 102, and is bonded to a rear-side (the lower side of FIG. 5) surface of the functional element 102 with the intermediation of the adhesive layer 103. The functional element 102 is covered by a first insulating layer 104, and is built in the insulating layer. A first wiring layer including first signal wiring 107 is provided on the first insulating layer 104, and element vias 106 that electrically connect the first signal wiring 107 to the functional element 102 are provided in the first insulating layer 104.

The first wiring layer is covered by a second insulating layer 108, and a ground layer 110 and a second wiring layer are provided on the second insulating layer 108. The ground layer 110 is formed of a ground plane that is ground wiring with a solid pattern, and the second wiring layer includes second signal wiring 111. In addition, second layer vias 109 are provided in the second insulating layer 108, and in FIG. 5, the second layer vias include second layer signal vias 109a and a second layer ground via 109b. The second layer signal vias 109a are vias that electrically connect the second signal wiring 111 to the first signal wiring 107. In addition, in the present invention, the metal plate 101 also functions as the ground. In FIG. 5, a first layer via 105 as a ground via is provided in the first insulating layer 104, and the ground layer 110 and the metal plate 101 are electrically connected to each other with the intermediation of at least the first layer via 105 and the second layer ground via 109b, and form a ground with the same potential.

In the present invention, the first signal wiring 107 is placed between the metal plate 101 that serves as the ground and the ground layer 110. In addition, in the present invention,

assuming that: the distance between the metal plate 101 and the first signal wiring 107 is d1; the distance between the first signal wiring 107 and the ground layer 110 is d2; the permittivity of the first insulating layer 104 is ε1; and the permittivity of the second insulating layer 108 is ε2, ε1/d1 is equal to or more than ε2/d2. This configuration can achieve the characteristic impedance matching of the first signal wiring included in the first wiring layer while improving the degree of freedom in wiring design.

Conventionally, a ground layer formed of a ground plane is provided in a wiring substrate, whereby the characteristic impedance matching of signal wirings placed in upper and lower layers is achieved. However, such a wider ground layer leads to a reduction in placement area of the signal wiring. In view of this, in the present invention, ε1/d1 is adjusted to be equal to or more than ε2/d2. With this configuration, a portion of the first signal wiring 107 that is located above a metal plate portion in a neighboring region of the functional element can form a microstripline structure with the metal plate 101 at a level equivalent to or higher than that with the ground layer 110. Hence, the area for providing the ground layer can be reduced in a region that is located above the metal plate portion in the neighboring region of the functional element, and signal wiring and power supply wiring can be further provided in this region. That is, it is possible to achieve the characteristic impedance matching of the first signal wiring included in the first wiring layer while improving the degree of freedom in wiring design.

In the present invention, the distance d1 denotes the shortest distance between the metal plate 101 and the first signal wiring 107. This shortest distance represents the distance between the upper surface of the metal plate 101 and the lower surface of the first signal wiring 107. In addition, the distance d2 denotes the distance between the first signal wiring 107 and the ground layer 110, and this distance represents the distance between the upper surface of the first signal wiring 107 and the lower surface of the ground layer 110.

In FIG. 5, the ground layer 110 is placed so as to surround the second signal wiring 111, and is formed into a planar plate-like pattern that spreads over the entire surface. The second signal wiring 111 of the second wiring layer is mainly formed of lands that each connect vias placed on the top and bottom thereof, but the present invention is not particularly limited thereto, and the second signal wiring 111 may include a wiring line portion. Particularly in the present invention, the portion of the first signal layer 107 that is located above the metal plate portion in the neighboring region of the functional element can form the microstripline structure with the metal plate serving as the ground at a level equivalent to or higher than that with the ground layer 110. Hence, the area of the ground layer can be reduced in the region that is located above the metal plate portion in the neighboring region of the functional element, and the area of the signal wiring can be increased accordingly. In addition, when the signal wiring including the wiring line portion is provided in the second wiring layer, it is desirable that the signal wiring be formed so as to be surrounded by the ground layer.

Further, in FIG. 5, a third insulating layer 112 is provided so as to cover the ground layer 110 and the second signal wiring 111. A solder mask 114 is provided on the third insulating layer 112. The solder mask 114 is provided with external connection terminals 115 that are used for connection with an external substrate and the like. In addition, third layer vias 113 are provided in the third insulating layer 112, and the third layer vias 113 include third layer signal vias 113a and a third layer ground via 113b. The third layer signal vias 113a are in contact with the second signal wiring 111, and the third layer ground via is in contact with the ground layer 110. In addition, the external connection terminals 115 include signal terminals 115a and a ground terminal 115b. The signal terminals 115a are in contact with the respective third layer signal vias 113a, and the ground terminal 115b is in contact with the third layer ground via 113b. For example, BGA balls are placed as the external connection terminals, and the external connection terminals are connected to the external substrate.

Furthermore, in FIG. 5, as regards the configuration of the external connection terminals 115, signal wiring and ground wiring may be exposed on the solder mask 114. That is, ground wiring and a third wiring layer including third signal wiring can be provided on the third insulating layer 112, and the solder mask 114 can be formed on the ground wiring and the third wiring layer such that parts of the ground wiring and the third wiring layer are exposed. In addition, the external connection terminals can, for example, protect the surface so as to prevent an outflow of solder.

The substrate with a built-in functional element having the configuration according to the present invention has excellent transmission characteristics with a matched characteristic impedance. Now, a characteristic impedance of wiring is described below.

The characteristic impedance depends on the distance between the wiring and a reference plane. The reason for this is as follows.

A characteristic impedance Z₀ of the wiring is given by the following expression assuming that: an inductance per unit length is L₀; and a capacitance per unit length between the reference plane and the wiring is C₀.

Z₀=√(L₀/C₀)[Ω] [Expression 1]

Note that the reference plane refers to a conductor with a fixed potential.

A capacitance C between the reference plane and the wiring is given by the following expression assuming that: the permittivity in vacuum is ε₀; the relative permittivity of an insulator provided between the wiring and the reference plane is εᵣ; the distance between the reference plane and the wiring is d; and the facing area between the reference plane and the wiring is S.

C=ε₀εᵣS/d[F] [Expression 2]

The calculation of the characteristic impedance requires the capacitance per unit length. The capacitance C₀ per wiring length of 1 cm is given by the following expression assuming that: the wiring width is w [mm]; and the distance between the wiring and the reference plane is h [mm].

C₀=10⁻²×ε₀εᵣw/h[F] [Expression 3]

In addition, the inductance per wiring length of 1 cm is given by the following expression corresponding to an expression for microstripline.

L₀=1.97×10⁻⁹×ln(2πh/w)[H] [Expression 4]

Consequently, the characteristic impedance Z₀ of the wiring can be obtained by substituting calculation results of (Expression 3) and (Expression 4) into (Expression 1). Accordingly, the characteristic impedance of the wiring depends on the distance h between the wiring and the reference plane. More specifically, the characteristic impedance of the wiring becomes larger as the distance h between the wiring and the reference plane becomes larger.

Note that, in the present invention, ε1/d1 is equal to or more than ε2/d2. That is, a condition is designated in which the electrostatic capacitance formed by the metal plate and the first signal wiring is equivalent to or larger than the electrostatic capacitance formed by the first signal wiring and the ground layer. On the basis of Expressions 3 and 4, when this condition is selected, the portion of the first signal wiring that is located above the metal plate portion in the neighboring region of the functional element can form the microstripline structure with the metal plate at a level equivalent to or higher than that with the ground layer.

d1 and d2 can be respectively controlled by the thicknesses of the first insulating layer and the second insulating layer. For example, as illustrated in FIG. 6, the distances d1 and d2 can be respectively selected by adjusting the thickness of a first insulating layer 204 and the thickness of a second insulating layer 208.

As illustrated in FIG. 5, the first insulating layer 104 and the second insulating layer 108 are formed using the same material so as to have the same thickness, whereby ε1/d1 can be made equal to ε2/d2. In this case, the portion of the first signal wiring 107 that is located above the metal plate portion in the neighboring region of the functional element can form the stripline structure more easily with the metal plate and the ground layer, and hence characteristic impedance matching can be achieved more easily, which is preferable. In addition, it is desirable that the characteristic impedance be matched to about 50 Ω.

FIG. 5 illustrates the case where the first insulating layer 104 and the second insulating layer 108 are made of the same material and where d1 is equal to d2. Alternatively, for example, as illustrated in FIG. 6, the same material is used for the first insulating layer 204 and the second insulating layer 208, and d2 is made larger than d1, whereby ε1/d1 can be made larger than ε2/d2.

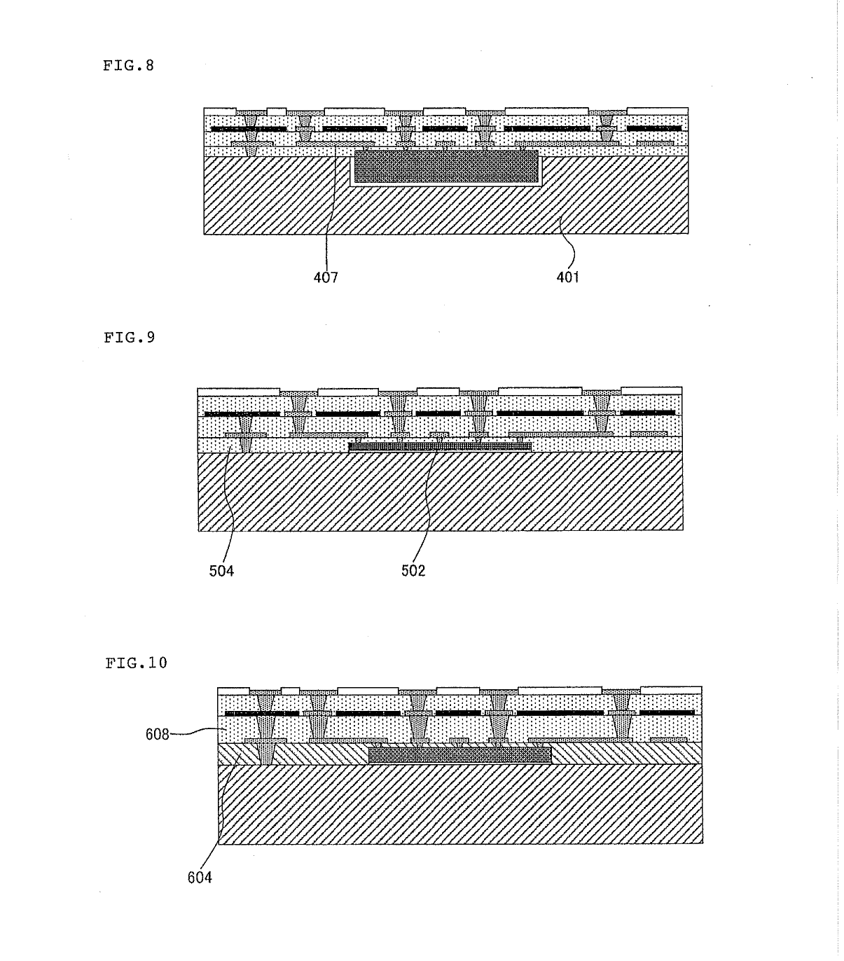

In addition, an example method of adjusting d1 involves, as illustrated in FIG. 7, forming a concave portion in a metal plate 301 and placing a functional element 302 in the concave portion. The concave portion is formed in the metal plate 301, and the functional element is placed in the concave portion, whereby the distance d1 between first signal wiring 307 and the metal plate 301 can be made smaller. Further, as illustrated in FIG. 8, a concave portion is formed more deeply than that in FIG. 7, whereby the distance d1 between first signal wiring 407 and a metal plate 401 can be made smaller than that in FIG. 7. Particularly in the present invention, it is preferable that ε1/d1 be made equal to ε2/d2 by adjusting the depth of the concave portion such that the metal plate serving as the ground, the first signal wiring, and the ground layer 10 form the stripline structure. In addition, it is desirable that the characteristic impedance be matched to about 50Ω by adjusting the depth of the concave portion.

In addition, as illustrated in FIG. 9, the thickness of a first insulating layer 504 is made smaller by making a functional element 502 thinner, whereby d1 can be smaller similarly.

In addition, ε1 and ε2 can be respectively controlled by the materials of the first insulating layer and the second insulating layer. As illustrated in FIG. 10, different materials can be used for a first insulating layer 604 and a second insulating layer 608.

In addition, it is preferable that the wiring line portion connecting the lands of the first signal wiring have substantially the same width over the first wiring layer.

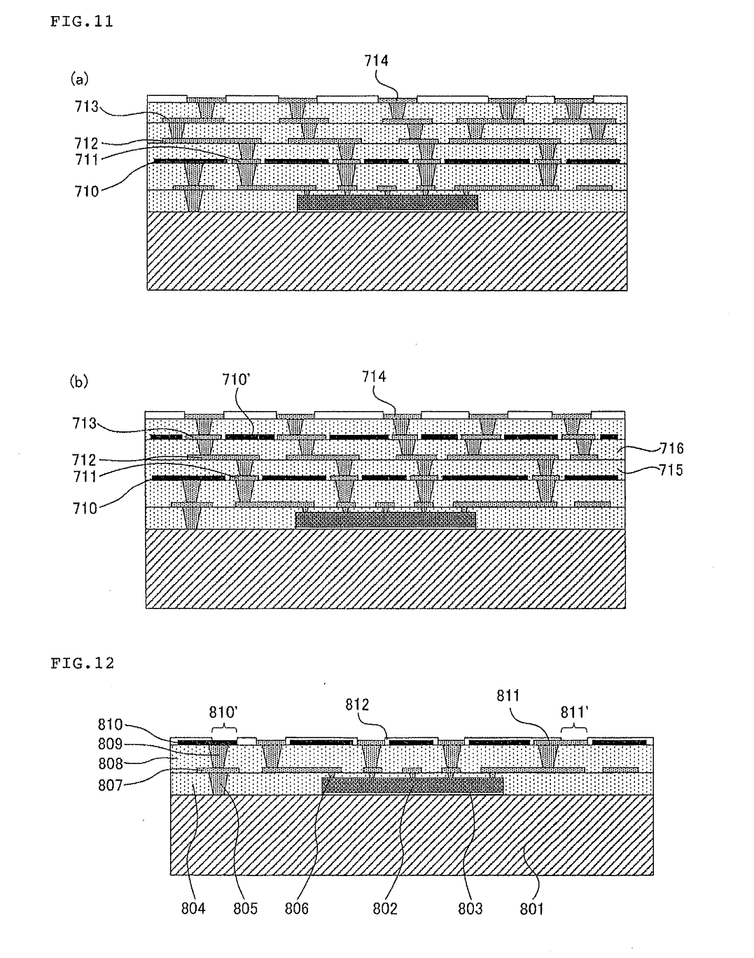

In addition, as illustrated in FIG. 11, one or more wiring layers can be further provided in upper layer(s) of a ground layer 710 and a second wiring layer including first signal wiring 711. That is, other wiring layers can be further provided on the outer side of the ground layer. For example, as illustrated in FIG. 11(a), a third wiring layer including third signal wiring 712 and a fourth wiring layer including fourth signal wiring 713 can be provided, and external connection terminals 714 can be provided thereabove.

In addition, a wiring layer can be sandwiched between ground layers that are respectively provided in upper and lower layers of the wiring layer. For example, as illustrated in FIG. 11(b), the third wiring layer including the third signal wiring 712 can be sandwiched between the ground layers 710 and 710′. That is, a third insulating layer 715 is formed so as to cover the second signal wiring 711 and the first ground layer 710, and the third wiring layer including the third signal wiring 712 is formed on the third insulating layer 715. A fourth insulating layer 716 is formed so as to cover the third wiring layer, and the second ground layer 710′ and the fourth wiring layer including the fourth signal wiring 713 are formed on the fourth insulating layer 716. The second ground layer 710′ is formed over the entire surface of the fourth insulating layer 716 except for the region in which the fourth wiring layer is formed.

In addition, FIG. 12 illustrates the present exemplary embodiment taken from the viewpoint of a reduction in thickness.

In FIG. 12, a functional element 802 such as a semiconductor chip is provided above a metal plate 801 that functions as a ground and a support, with the intermediation of an adhesive agent 803. The functional element 802 includes electrode terminals (not illustrated) on a circuit-side (the upper side of FIG. 12) surface thereof, and is placed above the metal plate 801 with the circuit surface thereof facing upward. The metal plate 801 supports the functional element 802, and is bonded to a rear-side (the lower side of FIG. 12) surface of the functional element 802 with the intermediation of the adhesive layer 803. The functional element 802 is covered by a first insulating layer 804, and is built in the insulating layer. A first wiring layer including first signal wiring 807 is provided on the first insulating layer 804, and element vias 806 that electrically connect the first signal wiring 807 to the functional element 802 are provided in the first insulating layer 804.

The first wiring layer is covered by a second insulating layer 808, and a ground layer 810 and a second wiring layer are provided on the second insulating layer 808. The ground layer 810 is formed of a ground plane that is ground wiring with a solid pattern, and the second wiring layer includes second signal wiring 811. The ground layer 810 is provided over substantially the entire surface of the second insulating layer 808 except for the region in which the second wiring layer is provided. In addition, second layer vias 809 are provided in the second insulating layer 808. The second layer vias include second layer signal vias and a second layer ground via. The second layer signal vias are vias that electrically connect the second signal wiring 811 to the first signal wiring 807. In addition, in the present invention, the metal plate 801 also functions as the ground. In FIG. 12, a first layer via 805 as a ground via is provided in the first insulating layer 804, and the ground layer 810 and the metal plate 801 are electrically connected to each other with the intermediation of at least the first layer via 805 and the second layer ground via, and form a ground with the same potential. In addition, assuming that: the distance between the metal plate 801 and the first signal wiring 807 is d1; the distance between the first signal wiring 807 and the ground layer 810 is d2; the permittivity of the first insulating layer 804 is ε1; and the permittivity of the second insulating layer 808 is ε2, ε1/d1 is equal to or more than ε2/d2. This configuration can achieve the characteristic impedance matching of the first signal wiring included in the first wiring layer while improving the degree of freedom in wiring design.

In addition, a third insulating layer 812 is provided so as to cover the ground layer 810 and the second signal wiring 811. The third insulating layer 812 is, for example, a solder mask. In addition, in FIG. 12, external connection terminals are formed by opening the third insulating layer 812 so as to expose parts of the second wiring layer and the ground layer 810. For example, the third insulating layer 812 is placed on the second wiring layer and the ground layer 810, and the third insulating layer 812 is etched such that parts of the second wiring layer and the ground layer 810 are exposed, whereby the external connection terminals can be formed. In FIG. 12, 810′ denotes a portion in which part of the ground layer 810 is exposed on the third insulating layer 812, and the portion forms a ground terminal. 811′ denotes a portion in which part of the second wiring layer is exposed on the third insulating layer 812, and the portion forms a signal terminal and a power supply terminal. For example, BGA balls are placed as the external connection terminals, and the external connection terminals are connected to the external substrate. In addition, the external connection terminals can, for example, protect the surface so as to prevent an outflow of solder.

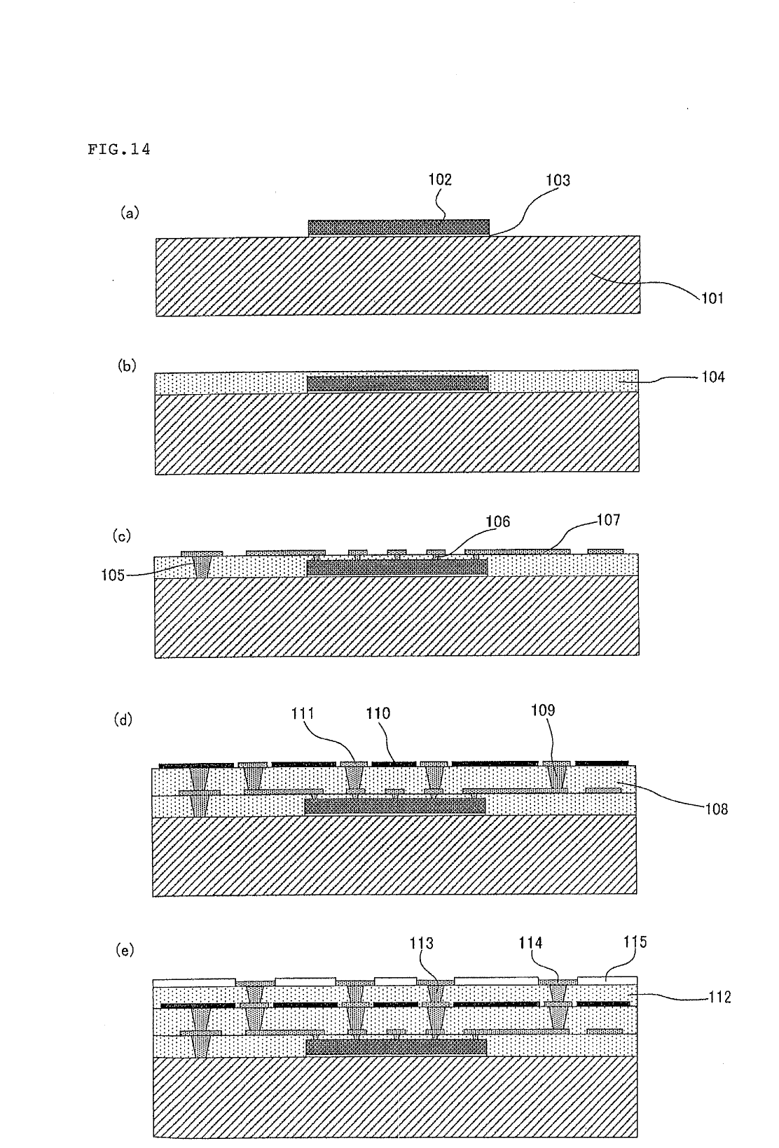

Next, a method of manufacturing the substrate with a built-in functional element according to the present invention is described with reference to FIG. 14. FIG. 14 are cross-sectional step views schematically illustrating steps of manufacturing the substrate with a built-in functional element according to the present invention. A semiconductor chip is used as the functional element in the following description. In addition, the present invention is not limited to the following method of manufacturing.

First, as illustrated in FIG. 14(a), the metal plate 101 is prepared.

Next, as illustrated in FIG. 14(b), the semiconductor chip 102 is mounted onto the metal plate 10′1 with the intermediation of the adhesive agent 103 with the electrode terminals (not illustrated) facing upward.

Next, as illustrated in FIG. 14(c), the first insulating layer 104, the first layer via 105, the element vias 106, and the first wiring layer including the first signal wiring 107 are formed. More specifically, the first insulating layer 104 is formed on the metal plate 101 so as to cover the electrode terminal-side surface of the semiconductor chip 102 and the side walls thereof. In addition, the element vias 106 connected to the respective electrode terminals and the first layer via 105 connected to the metal plate 101 are formed in the first insulating layer 104. In addition, as illustrated in FIG. 14(c), the first wiring layer including the first signal wiring 107 is formed on the first insulating layer 104 including the element vias 106 and the first layer via 105.

Next, as illustrated in FIG. 14(d), the second insulating layer 108, the second layer vias 109, the ground layer 110, and the second wiring layer including the second signal wiring 111 are formed. More specifically, the second insulating layer 108 is formed so as to cover the first wiring layer including the first signal wiring 107, and the second layer vias 109 are formed in the second insulating layer 108. In addition, the ground layer 110 and the second wiring layer including the second signal wiring 111 are formed on the second insulating layer 108.

Next, as illustrated in FIG. 14(e), the third insulating layer 112, the third layer vias 113, the solder mask 114, and the external connection terminals 115 are formed. More specifically, the third insulating layer 112 is formed so as to cover the second wiring layer including the second signal wiring 111 and the ground layer 110, and the third layer vias 113 are formed in the third insulating layer 112. In addition, the external connection terminals 115 and the solder mask 114 are formed on the third insulating layer 112.

This application claims priority based on Japanese Patent Application No. 2010-087804 filed on Apr. 6, 2010, the entire disclosure of which is incorporated herein by reference.

Hereinabove, the invention of the present application is described by way of the exemplary embodiments and the example, and the invention of the present application is not limited to the exemplary embodiments and the example described above. Various modifications that a person skilled in the art can understand can be made to the configurations and details of the invention of the present application, within the scope of the invention of the present application.

### REFERENCE SIGNS LIST

1, 31 metal plate
2, 32 functional element
3, 33 adhesive agent
4, 24, 34 first insulating layer
5, 35 first layer via
6, 36 element via
7, 37 first signal wiring
8, 28, 38 second insulating layer
9, 39 second layer via
9a, 39a second layer signal via
9b, 39b second layer ground via
10, 40, 70 ground layer (first ground layer)
70′ second ground layer
11, 41, 71 second signal wiring
72 third signal wiring
73 fourth signal wiring
12, 42, 75 third insulating layer
76 fourth insulating layer
13 third layer via
13a third layer signal via
13b third layer ground via
14 solder mask
15, 74 external connection terminal
15a signal terminal
15b ground terminal
40′ ground terminal
41′ signal terminal
101, 301, 401, 801 metal plate
102, 302, 502, 802 functional element
103, 803 adhesive agent
104, 204, 504, 604, 804 first insulating layer
105, 805 first layer via
106, 806 element via
107, 307, 407, 807 first signal wiring
108, 208, 608, 808 second insulating layer
109, 809 second layer via
109a second layer signal via
109b second layer ground via
110, 710, 810 ground layer
111, 711, 811 second signal wiring
712 third signal wiring
713 fourth signal wiring
112, 715 third insulating layer
716 fourth insulating layer
113 third layer via
113a third layer signal via
113b third layer ground via
114 solder mask
115, 714 external connection terminal
115a signal terminal
115b ground terminal
810′ ground terminal
811′ signal terminal

1. A substrate with a built-in functional element, comprising:
a metal plate that includes a concave portion and serves as a ground;
the functional element that is placed in the concave portion and includes an electrode terminal;
a first insulating layer that covers the functional element and is placed in contact with the metal plate;
a first wiring layer including first signal wiring that is opposite the metal plate with the first insulating layer being interposed therebetween;
a second insulating layer that covers the first wiring layer; and
a ground layer formed of a ground plane that is opposite the first wiring layer with the second insulating layer being interposed therebetween.

2. The substrate with a built-in functional element according to claim 1, wherein
the first signal wiring forms a stripline structure with the ground layer and the metal plate.

3. The substrate with a built-in functional element according to claim 1, wherein
the ground layer and the metal plate are electrically connected to each other, and form a ground with the same potential.

4. The substrate with a built-in functional element according to claim 1, further comprising a second wiring layer that includes second signal wiring electrically connected to the first signal wiring and is placed in contact with the second insulating layer so as to be surrounded by the ground layer.

5. The substrate with a built-in functional element according to claim 1, further comprising one or more other wiring layers on an outer side of the ground layer.

6. The substrate with a built-in functional element according to claim 1, further comprising external connection terminals, wherein
at least one of the external connection terminals is electrically connected to the electrode terminal.

7. The substrate with a built-in functional element according to claim 6, wherein
the external connection terminals include:
a signal terminal that is electrically connected to the functional element with an intermediation of at least the first signal wiring; and
a ground terminal electrically connected to the ground layer.

8. The substrate with a built-in functional element according to claim 4, further comprising a third insulating layer that covers the ground layer and the second signal wiring, wherein
part of the ground layer and part of the second signal wiring are exposed on the third insulating layer, and function as external connection terminals.

9. A substrate with a built-in functional element, comprising:
the functional element including an electrode terminal;
a metal plate that supports the functional element and serves as a ground;
a first insulating layer that covers the functional element and is placed in contact with the metal plate;
a first wiring layer including first signal wiring that is opposite the metal plate with the first insulating layer being interposed therebetween;
a second insulating layer that covers the first wiring layer; and
a ground layer formed of a ground plane that is opposite the first wiring layer with the second insulating layer being interposed therebetween, wherein
assuming that: a shortest distance between the metal plate and the first signal wiring is d1; a distance between the first signal wiring and the ground layer is d2; a permittivity of the first insulating layer is ε1; and a permittivity of the second insulating layer is ε2, ε1/d1 is equal to or more than ε2/d2.

10. The substrate with a built-in functional element according to claim 9, wherein
the metal plate includes a concave portion, and
the functional element is placed in and supported by the concave portion.

11. The substrate with a built-in functional element according to claim 9, wherein
the ground layer and the metal plate are electrically connected to each other, and form a ground with the same potential.

12. The substrate with a built-in functional element according to claim 9, further comprising a second wiring layer that includes second signal wiring electrically connected to the first signal wiring and is placed in contact with the second insulating layer so as to be surrounded by the ground layer.

13. The substrate with a built-in functional element according to claim 9, further comprising one or more other wiring layers on an outer side of the ground layer.

14. The substrate with a built-in functional element according to claim 9, further comprising external connection terminals, wherein
at least one of the external connection terminals is electrically connected to the electrode terminal.

15. The substrate with a built-in functional element according to claim 14, wherein
the external connection terminals each include:
a signal terminal that is electrically connected to the functional element with an intermediation of at least the first signal wiring; and
a ground terminal electrically connected to the ground layer.

16. The substrate with a built-in functional element according to claim 12, further comprising a third insulating layer that covers the ground layer and the second signal wiring, wherein
part of the ground layer and part of the second signal wiring are exposed on the third insulating layer, and function as external connection terminals.

17. An electronic device comprising the substrate with a built-in functional element according to claim 1.

18. An electronic device comprising the substrate with a built-in functional element according to claim 9.

19. The substrate with a built-in functional element according to claim 2, wherein
the ground layer and the metal plate are electrically connected to each other, and form a ground with the same potential.

20. The substrate with a built-in functional element according to claim 2, further comprising a second wiring layer that includes second signal wiring electrically connected to the first signal wiring and is placed in contact with the second insulating layer so as to be surrounded by the ground layer.
